(19) United States
(12) Patent Application Publication
(10) Pub. No.: US 2025/0287708 A1
(43) Pub. Date: Sep. 11, 2025

(54) Carrier-Free Micro Light Source Image Sensing Device

(71) Applicant: Medimaging Integrated Solution, Inc., Hsinchu (TW)

(72) Inventors: Chu-Ming Cheng, Hsinchu (TW); SHANGYI WU, Hsinchu (TW)

(21) Appl. No.: 18/925,788

(22) Filed: Oct. 24, 2024

(30) Foreign Application Priority Data
Mar. 7, 2024 (TW) 113202334

(51) Int. Cl. H01L 27/146; H01L 31/0203; H01L 31/12

(52) U.S. Cl. CPC H10F 39/198; H10F 39/8057; H10F 39/811; H10F 55/18; H10F 77/50

(57) ABSTRACT

A carrier-free micro light source image sensing device includes an image sensor, a light source module, and a packaging layer. The image sensor is placed on a first positioning area of a temporary carrier; the light source module is adjacent to one side of the image sensor. The light source module includes a supporter and a light-emitting element. The light source module is placed on a second positioning area of a temporary carrier. The altitude of a light-emitting face of the light source element is lower than or equal to that of a sensing face of the image sensor. The packaging layer covers the image sensor and the light source module but reveals the sensing face and the light-emitting face. The temporary carrier is removed after the packaging layer is cured. The present invention can minimize the size of the light source image sensing device, simplify the production process, improve the overall product quality, increase the signal-to-noise ratio, and enhance image quality.

### 1. FIELD OF THE INVENTION

The present invention relates to an endoscopic light source image sensing device, particularly to a carrier-free micro light source image sensing device.

### 2. DESCRIPTION OF THE PRIOR ART

In general, the fabrication of an endoscopic light source image sensing module needs a piece of carrier for carrying an optical sensing instrument and a light source module (such as LED). If the carrier is a flexible printed circuit (FPC), the fabrication needs an additional CAP process to cover the optical sensing device or package the optical sensing device for protecting the surface or functioning as a light shield layer. If the position of LED needs raising, FPC must be bent and then fixed. Thus, the volume of the overall optical image module will become too larger to be assembled in fabrication. Besides, a resin must be filled into the gap between the CAP structure and the optical sensor to fix them. Therefore, a sufficient space must be preserved to allow a resin-dispensing needle to enter the gap, which will further increase the volume of the overall module and impair the miniaturization of endoscopes.

At present, all the existing light source image sensing modules use carriers. Thus, the overall height or length of the module must involve the thickness of the carrier. The abovementioned technology can fabricate endoscopes easily, but it is not a technology to realize miniaturization. Accordingly, the present invention proposes a carrier-free micro light source image sensing device to overcome the conventional problems.

### SUMMARY OF THE INVENTION

One objective of the present invention is to provide a carrier-free micro light source image sensing device, which is applicable to endoscopes, wherein the size of the light source image sensing device is minimized, whereby to simplify the fabrication process and promote the overall mass-production quality, and whereby to avoid the signal loss induced by using a carrier or an adaptor board, raise the signal-to-noise ratio, and enhance the image quality.

In order to achieve the abovementioned objective, the present invention provides a carrier-free micro light source image sensing device, which comprises an image sensor, a light source module, and a packaging layer. The image sensor has a sensing face and a connection face opposite to the sensing face. The connection face contacts the surface of a temporary carrier and is corresponding to a first positioning area of the temporary carrier. The light source module is adjacent to one side of the image sensor and includes a supporter and a light-emitting element. The supporter of the light source module contacts the surface of the temporary carrier and is corresponding to a second positioning area. The second positioning area is adjacent to the first positioning area. The light-emitting element is disposed on the supporter and has a light-emitting face. The altitude of the light-emitting face is lower than or equal to the altitude of the sensing face of the image sensor. The packaging layer covers the image sensor and the light-emitting element except the sensing face and the light-emitting face. The packaging layer fixes the image sensor and the light source module to form a packaged workpiece. Then, the temporary carrier is removed from the packaged workpiece to form a carrier-free micro light source image sensing device.

In one embodiment, the light-emitting module further comprises an intermediate supporter, which is disposed between the supporter and the light-emitting element.

In one embodiment, the light-emitting module further comprises a light shield layer, which encapsulates the perimeter of the light-emitting module but reveals the light-emitting face.

In one embodiment, the light-emitting element is a light-emitting diode (LED) chip.

In one embodiment, the light source module further comprises a fluorescent powder layer, which covers the light-emitting element.

In one embodiment, the supporter includes a first connection member and a second connection member. The first connection member is disposed on the top surface of the supporter, and the second connection member is disposed on the bottom surface of the supporter. The first connection member is connected with the bottom of the light-emitting element or the bottom of the intermediate supporter.

In one embodiment, the carrier-free micro light source image sensing device further comprises a transmission wire. The supporter has a second connection member on the bottom surface thereof. The transmission wire is connected with the connection face of the image sensor and the second connection member of the supporter.

In one embodiment, the carrier-free micro light source image sensing device further comprises a transparent covering layer. The transparent covering layer is disposed on the surface of the packaging layer and covers the light source module. The transparent covering layer does not cover the sensing face of the image sensor.

In one embodiment, the carrier-free micro light source image sensing device further comprises an electronic element. The bottom of the electronic element contacts the temporary carrier and is corresponding to a third positioning area. The electronic element is disposed on one side of the light source module, which is away from the image sensor. The packaging layer covers the electronic element.

Because the carrier-free micro light source image sensing device of the present invention needn't use a carrier, the overall mass-production efficiency is raised, and the overall module size is highly miniaturized. In practical application, the wire can be directly soldered to the image sensor and the light source module. Thus, the present invention can avoid the signal loss resulting from using a carrier or another adapter board. Further, the signal-to-noise ratio is increased, and the image quality is enhanced. Besides, the light source module may be equipped with LEDs emitting lights of different wavelengths or colors, such as white light LEDs and infrared LEDs, which may be switched on respectively or simultaneously to provide illumination according to requirement. Therefore, the present invention can increase the design flexibility and expand the application range.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein

FIG. 1A is a diagram schematically showing a carrier-free micro light source image sensing device according to a first embodiment of the present invention, wherein the temporary carrier is separated from the carrier-free micro light source image sensing device;

FIG. 1B is a diagram schematically showing the carrier-free micro light source image sensing device according to the first embodiment of the present invention;

FIGS. 2A-2C are diagrams schematically showing the temporary carrier and the carrier-free micro light source image sensing device according to the first embodiment of the present invention;

FIGS. 3-6 are diagrams schematically showing several embodiments of the light source module of the carrier-free micro light source image sensing device according to the first embodiment of the present invention;

FIG. 7 is a diagram schematically showing a carrier-free micro light source image sensing device according to a second embodiment of the present invention;

FIG. 8 is a diagram schematically showing a local area of the temporary carrier of a carrier-free micro light source image sensing device according to a third embodiment of the present invention; and

FIG. 9 is a diagram schematically showing the carrier-free micro light source image sensing device according to the third embodiment of the present invention.

### DESCRIPTION OF THE PREFERRED EMBODIMENTS

Various embodiments of the present invention will be described in detail below and illustrated in conjunction with the accompanying drawings. In addition to these detailed descriptions, the present invention can be widely implemented in other embodiments, and apparent alternations, modifications and equivalent changes of any mentioned embodiments are all included within the scope of the present invention and based on the scope of the Claims. In the descriptions of the specification, in order to make readers have a more complete understanding about the present invention, many specific details are provided; however, the present invention may be implemented without parts of or all the specific details. In addition, the well-known steps or elements are not described in detail, in order to avoid unnecessary limitations to the present invention. Same or similar elements in Figures will be indicated by same or similar reference numbers. It is noted that the Figures are schematic and may not represent the actual size or number of the elements. For clearness of the Figures, some details may not be fully depicted.

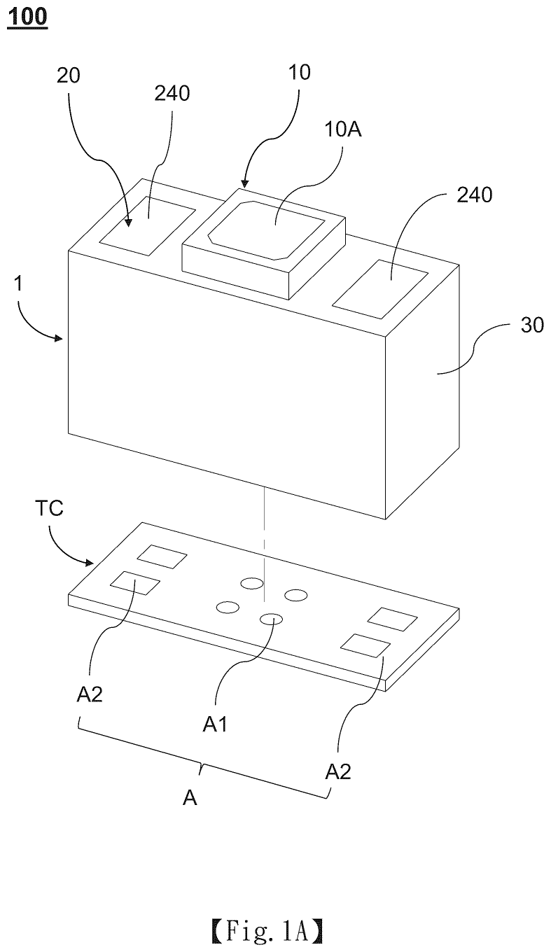

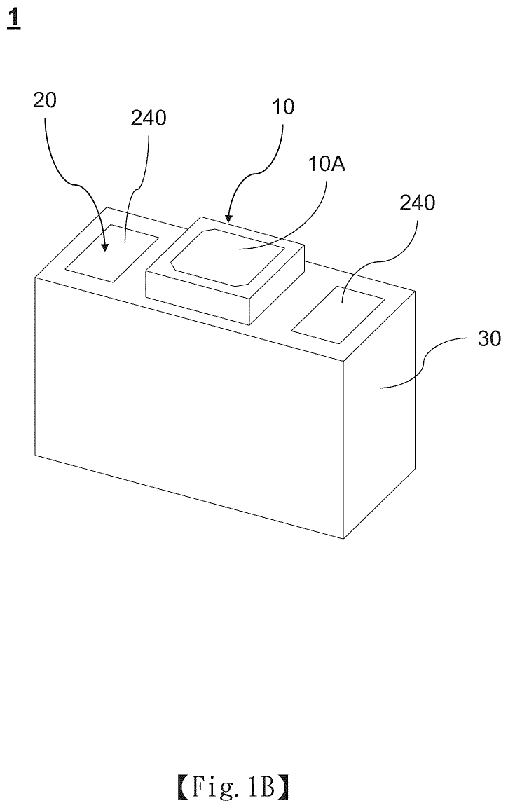

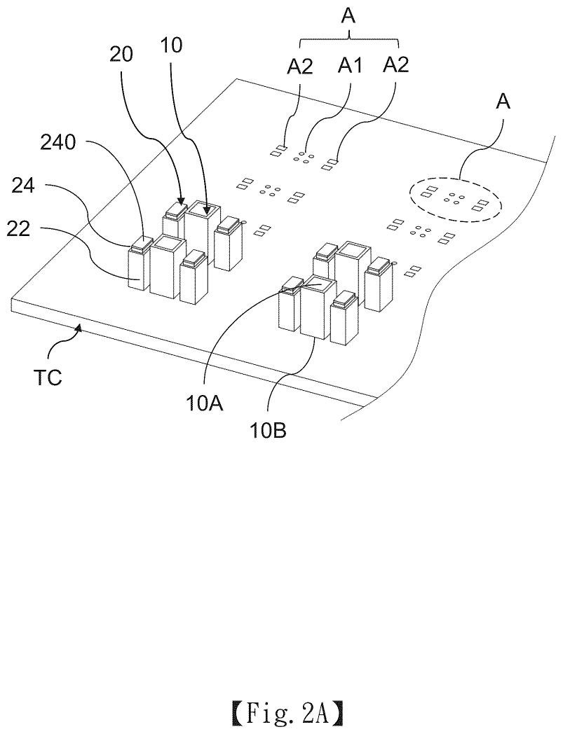

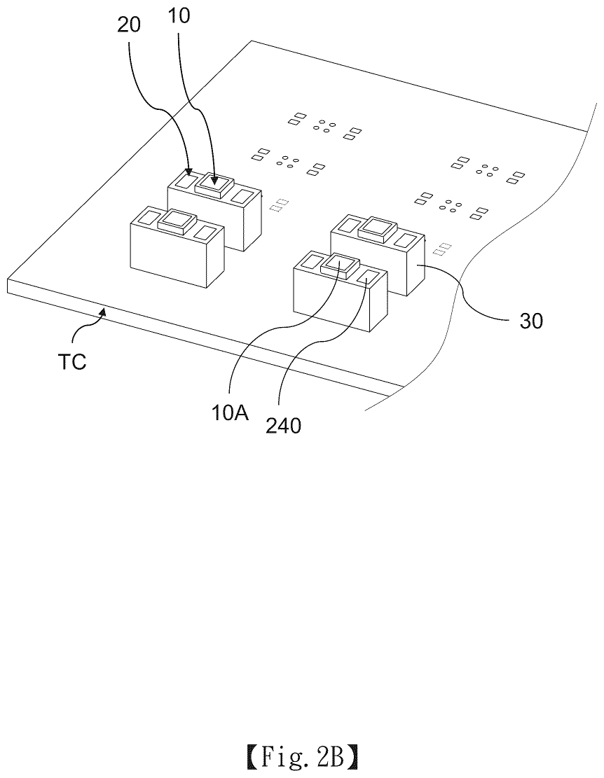

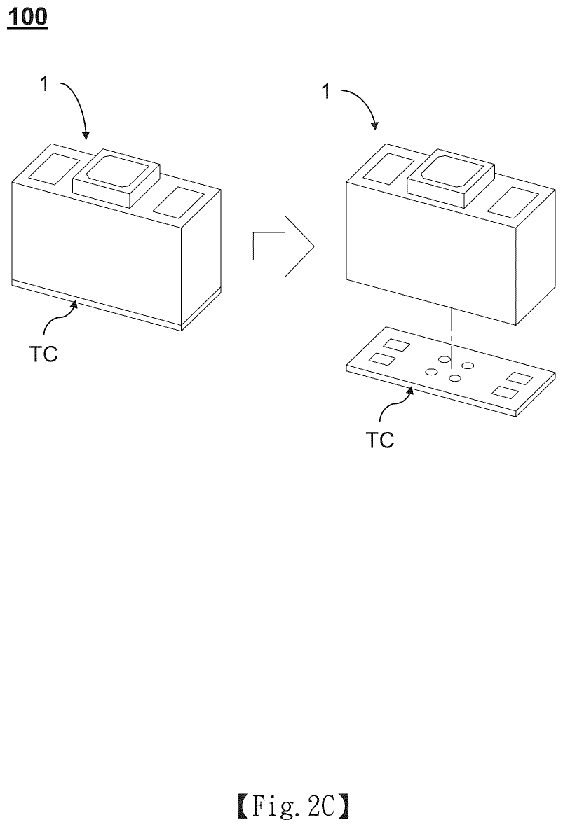

Refer to FIG. 1A and FIG. 1B. The carrier-free micro light source image sensing device 1 of the present invention comprises an image sensor 10, light source modules 20, and a packaging layer 30. The image sensor 10 has a sensing face 10A and a connection face 10B, which are opposite to each other. The symbol 10B in FIG. 2A indicates the connection face. The connection face 10B contacts a temporary carrier TC and is corresponding to a first positioning area A1 of the temporary carrier TC. The light source module 20 is adjacent to one side of the image sensor 10. The packaging layer 30 covers the image sensor 10 and the light source module 20 except the sensing face 10A of the image sensor 10 and a light-emitting face 240 of the light-emitting element 24. Thus, the packaging layer 30 fixes the image sensor 10 and the light-emitting module 20 but reveals the sensing face 10A of the image sensor 10 and the light-emitting face 240 of the light source module 20, whereby to form a packaged workpiece 100. The temporary carrier TC is removed to form the carrier-free micro light source image sensing device 1, as shown in FIG. 1B. In the embodiment, there are two light-emitting modules 20. However, the present invention only demands that there should be at least one light-emitting module 20. If there are more than one light-emitting module 20, the light-emitting modules 20 may be disposed in the perimeter of the image sensor 10 or in asymmetric positions. The present invention is not limited by the layout in FIG. 1. Besides, the light-emitting module 20 may be equipped with several LEDs respectively emitting lights of different wavelengths or colors, such as white light LEDs and infrared LEDs, which may be switched on respectively or simultaneously to provide illumination according to requirement.

Refer to FIGS. 2A-2C. Below are introduced the technical characteristics of the temporary carrier TC and the carrier-free micro light source image sensing device 1. As shown in FIG. 2A, there is a plurality of groups of positioning symbols A, which are arranged in array and to be recognized by the fabrication apparatus in the succeeding process. Each group of positioning symbols A includes at least one first positioning area A1 and at least one second positioning area A2. The first positioning area A1 neighbors the second positioning area A2. The first positioning area A1 includes at least one positioning point for the positioning of the image sensor 10. The second positioning area A2 includes at least one positioning point for the positioning of the light-emitting module 20. The first positioning area A1 and the second positioning area A2 may be fabricated in a printing method or another method. The numbers, distances, and positions of the first positioning area A1 and the second positioning area A2 are designed in advance, which favors the miniaturization of the overall device and enables the image sensors 10 and the light-emitting modules 20 to be precisely positioned in fabrication, whereby waste material is reduced in fabrication. The light-emitting module 20 includes a supporter 22 and a light-emitting element 24. The supporter 22 of the light-emitting module 20 contacts the temporary carrier TC and is corresponding to the second positioning area A2 of the temporary carrier TC. The light-emitting element 24 is disposed on supporter 22 and has a light-emitting face 240. The altitude of the light-emitting face 240 of the light-emitting element 24 is preferably smaller than or equal to the altitude of the sensing face 10A of the image sensor 10. The altitude of the light-emitting face 240 is correlated with the height of the supporter 22. Therefore, the height of the supporter 22 may be adjusted to meet the illumination requirement. As shown in FIG. 2B, after the image sensor 10 and the light-emitting module 20 have been secured to the temporary carrier TC, a light shield material is filled into the areas between and around the image sensor 10 and the light-emitting module 20. The packaging layer 30 is formed after the light shield material is cured. It should be noted: the packaging layer 30 is not allowed to cover the sensing face 10A of the image sensor 10 and the light-emitting face 240 of the light-emitting element 24. In other words, the packaging layer 30 must reveal the sensing face 10A and the light-emitting face 240 to prevent the light of the light-emitting element 24 from entering the image sensor 10 lest stray light affect image quality. The cured light shield material fixes and protects the image sensor 10 and the light-emitting module 20. As shown in FIG. 2C, after the packaging layer 30 is cured, the packaging layer 30 fixes the image sensor 10 and the light-emitting module 20 to form a packaged workpiece 100. The temporary carrier TC is cut off along the boundary of the packaged workpiece 100 or along cutting lines to remove the temporary carrier TC. Thus is obtained the carrier-free micro light source image sensing device 1.

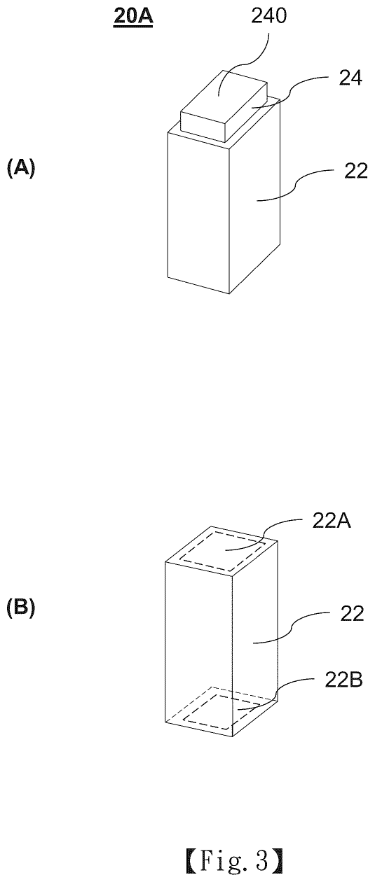

FIGS. 3-6 will introduce several embodiments of the light source module. In FIG. 3, Section (A) shows the overall structure of the light source module 20A; Section (B) shows the structure of the supporter 22. The light source module 20A includes the supporter 22 and the light-emitting element 24. The supporter 22 has a first connection member 22A and a second connection member 22B. The first connection member 22A is disposed on the top surface of the supporter 22; the second connection member 22B is disposed on the bottom surface of the supporter 22. The first connection member 22A is joined with the bottom of the light-emitting element 24. The light-emitting element 24 is a light-emitting diode (LED) chip. Different LED chips respectively having different wavelengths and different color temperatures may be used to meet different requirements. The surface and interior of the supporter 22 has circuits and solder pads, which enable the LED chip to be disposed on the surface of the supporter 22 and connected with the internal circuits of the supporter 22.

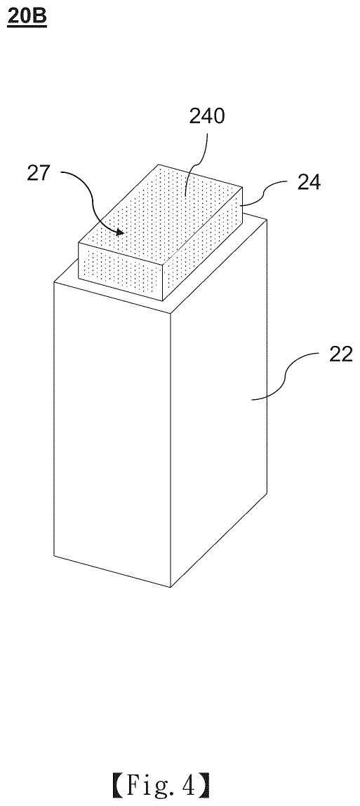

Refer to FIG. 4. The light source module 20B includes a supporter 22, a light-emitting element 24, and a fluorescent powder layer 27. The embodiment is different from the abovementioned embodiment in the fluorescent powder layer 27. The characteristics of the supporter 22 have been described in detail hereinbefore and will not repeat herein. The fluorescent powder layer 27 covers the light-emitting element 24 and emits a light source suitable to terminal products, such as endoscopes. The light-emitting element 24 may be a light-emitting diode (LED). The fluorescent powder layer 27 is coated on the surfaces of the light-emitting diode. For example, a blue light LED excites the yellow light fluorescent powder (such as YAG); the complementary yellow light and blue light are mixed to form high-brightness white light. Thus, is obtained a white light LED. Therefore, the fluorescent powder layer 27 can vary the color of the light emitted by LED and enhance the light efficiency.

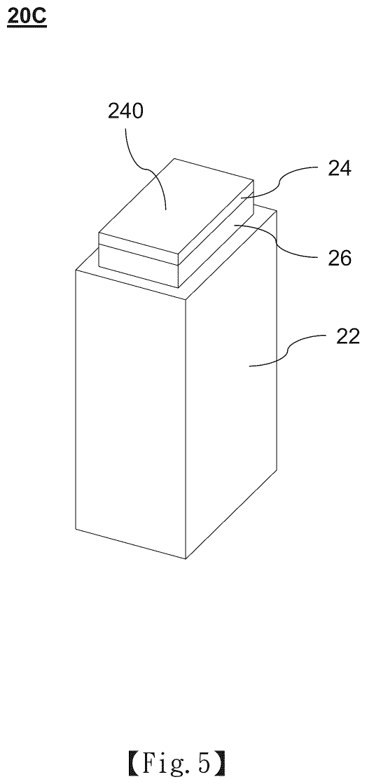

Refer to FIG. 5. The light source module 20C includes a supporter 22, a light-emitting element 24, and an intermediate supporter 26. The embodiment is different from the abovementioned embodiment in the intermediate supporter 26. The characteristics of the supporter 22 and the light-emitting element 24 have been described in detail hereinbefore and will not repeat herein. The intermediate supporter 26 is disposed between the supporter 22 and the light-emitting element 24, able to increase the stability of the fabrication process, promote the performance of the products, and provide more flexibility of design. The top surface and bottom surface of the intermediate supporter 26 are respectively connected with the light-emitting element 24 and the supporter 22, providing an effective heat-conduction path and favoring heat dissipation of the light-emitting element 24, whereby to prevent the interior circuits of the supporter 22 from being damaged by poor heat dissipation of the light-emitting element 24 and increase the reliability and service life of the products. The intermediate supporter 26 may provide a stabilization layer for the succeeding electric processing or increase the flexibility of design. For example, the intermediate supporter 26 may be used in circuit fabrication, test, miniaturizing/thinning processes, adding more functional layers, or using different materials to promote the overall performance of the modules.

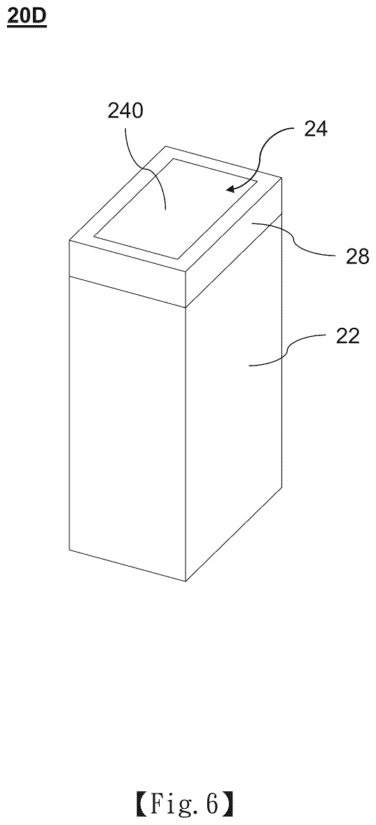

Refer to FIG. 6. The light source module 20D includes a supporter 22, a light-emitting element 24, and a light shield layer 28. The embodiment is different from the abovementioned embodiment in the light shield layer 28. The characteristics of the supporter 22 and the light-emitting element 24 have been described in detail hereinbefore and will not repeat herein. The light shield layer 28 covers the perimeter of the light-emitting element 24 but reveals the light-emitting face 240. The light shield layer 28 may be made of a light shield material having a diffusing or scattering function. The light shield layer 28 can increase the stability and the light-emitting efficiency and prevent from the interference of external light sources.

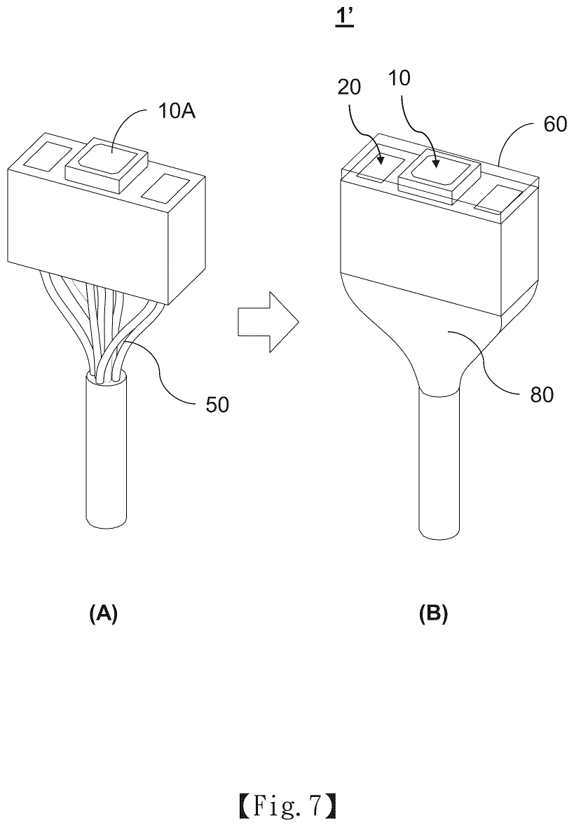

Refer to FIG. 7. The embodiment is different from the first embodiment in transmission wires 50 and a transparent covering layer 60. The identical elements will not repeat herein. The carrier-free micro light source image sensing device 1′ of the present invention further comprises transmission wires 50 and a transparent covering layer 60. The bottom surface of the supporter 22 has a second connection member (indicated by the symbol 22B in FIG. 3 (B)). The transmission wires 50 may be connected with the connection face (indicated by the symbol 10B in FIG. 2A) of the image sensor 10 and the second connection member of the supporter 22. The transparent covering layer 60 is disposed on the surface of the packaging layer 30 and covers the light-emitting module 20, but the transparent covering layer 60 does not cover the sensing face 10A of the image sensor 10. In other words, the transparent covering layer 60 reveals the sensing face 10A. The transparent covering layer 60 may be but is not limited to be made of a transparent resin material. The transparent covering layer 60 covers the light source module 20 and protects the light-emitting element 24, but the transparent covering layer 60 is not allowed to cover the sensing face 10A of the image sensor 10.

The transmission wires 50 may directly connect the wire, the image sensor 10 and the light source module 20 in a soldering method without using a carrier or any adapter material, whereby to eliminate the source of noise completely, increase the signal-to-noise ratio and enhance the image quality. Besides, a protective resin material 80 may be disposed on the exterior of the transmission wires 50, whereby to prevent the transmission wires from dropping off and avoid interruption of signals and power supply.

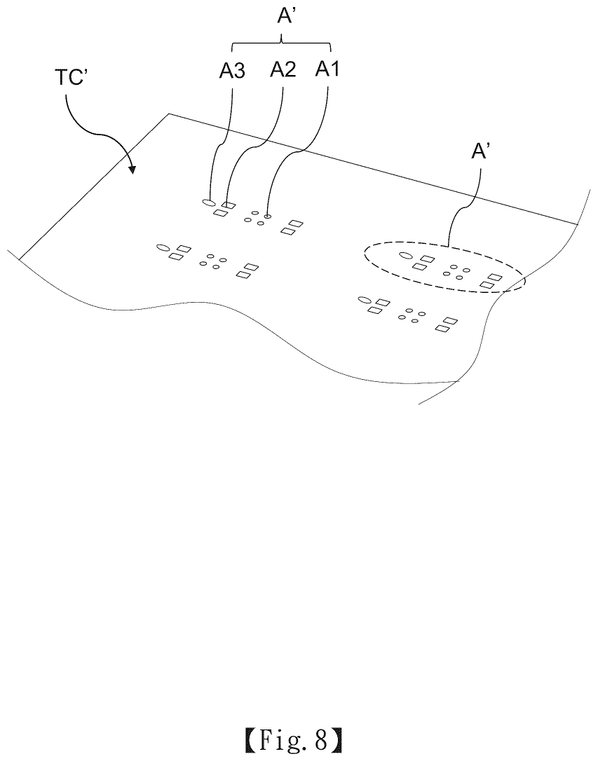

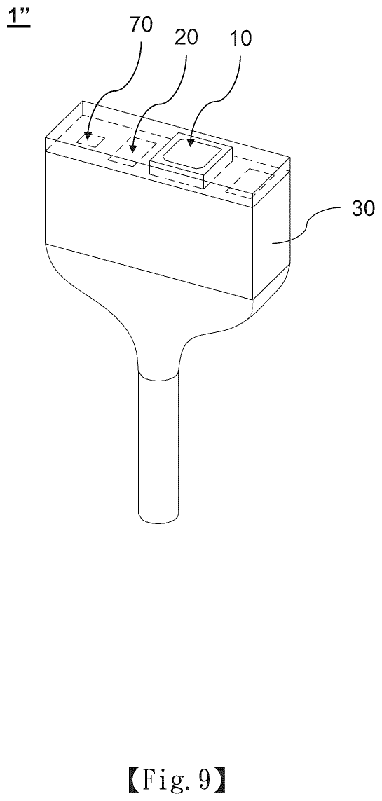

Refer to FIG. 8 and FIG. 9. The embodiment is different from the second embodiment shown in FIG. 7 in the temporary carrier TC′ and an electronic element 70. The identical elements will not repeat herein. The carrier-free micro light source image sensing device 1″ of the present invention further comprises an electronic element 70. Each group of the positioning symbols A′ on the temporary carrier TC further includes a third position area A3 in addition to the first positioning area A1 and the second positioning area A2. The third positioning area A3 may be disposed on one side of the second positioning area A2, which is away from the first positioning area A1. The bottom of the electronic element 70 contacts the surface of the temporary carrier TC′ and is corresponding to the third positioning area A3. The electronic element 70 is disposed on one side of the light source module 20, which is away from the image sensor 10. The packaging layer 30 covers the electronic element 70. The electronic element 70 may be but is not limited to be a functional element, a thermistor, or a pressure sensor. For example, while the carrier-free micro light source image sensing device 1″ of the present invention is applied to an endoscope, the thermistor may detect temperature variation and provide temperature data to enhance the accuracy of image analysis; the pressure sensor may detect the pressure of liquid or gas and provide pressure data, such as the contact pressure on the inspected object, whereby the inspection not only performs observation but also provides abundant data for image analysis. Therefore, the present invention can increase the performance and application field of the module and endoscope.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the appended claims.

1. A carrier-free micro light source image sensing device, comprising
an image sensor, having a sensing face and a connection face opposite to the sensing face, wherein the connection face contacts a surface of a temporary carrier and is corresponding to a first positioning area of the temporary carrier;
a light source module, adjacent to one side of the image sensor and including
a supporter, contacting the surface of the temporary carrier and corresponding to a second positioning area of the temporary carrier, wherein the second positioning area is adjacent to the first positioning area; and
a light-emitting element, disposed on the supporter and having a light-emitting face, wherein an altitude of the light-emitting face is lower than or equal to an altitude of the sensing face of the image sensor; and
a packaging layer, covering the image sensor and the light-emitting element but revealing the sensing face and the light-emitting face, wherein the packaging layer fixes the image sensor and the light source module to form a packaged workpiece,
wherein the temporary carrier is removed from the packaged workpiece to form the carrier-free micro light source image sensing device.

2. The carrier-free micro light source image sensing device according to claim 1, wherein the light-emitting module further comprises an intermediate supporter, which is disposed between the supporter and the light-emitting element.

3. The carrier-free micro light source image sensing device according to claim 1, wherein the light-emitting module further comprises a light shield layer, which encapsulates a perimeter of the light-emitting element but reveals the light-emitting face.

4. The carrier-free micro light source image sensing device according to claim 1, wherein the light-emitting element is a light-emitting diode (LED) chip.

5. The carrier-free micro light source image sensing device according to claim 1, wherein the light source module further comprises a fluorescent powder layer, which covers the light-emitting element.

6. The carrier-free micro light source image sensing device according to claim 1, wherein the supporter includes a first connection member and a second connection member; the first connection member is disposed on a top surface of the supporter, and the second connection member is disposed on a bottom of the supporter; the first connection member is connected with a bottom of the light-emitting element.

7. The carrier-free micro light source image sensing device according to claim 2, wherein the supporter includes a first connection member and a second connection member; the first connection member is disposed on the top surface of the supporter, and the second connection member is disposed on the bottom of the supporter; the first connection member is connected with a bottom of the light-emitting element or a bottom of the intermediate supporter.

8. The carrier-free micro light source image sensing device according to claim 1, further comprising a transmission wire, wherein the supporter has a second connection member on a bottom surface thereof; the transmission wire is connected with the connection face of the image sensor and the second connection member of the supporter.

9. The carrier-free micro light source image sensing device according to claim 1, further comprising a transparent covering layer, which is disposed on a surface of the packaging layer and covers the light source module; the transparent covering layer does not cover the sensing face of the image sensor.

10. The carrier-free micro light source image sensing device according to claim 1, further comprising an electronic element, wherein a bottom of the electronic element contacts the temporary carrier and is corresponding to a third positioning area of the temporary carrier; the electronic element is disposed on one side of the light source module, which is away from the image sensor; the packaging layer covers the electronic element.

11. The carrier-free micro light source image sensing device according to claim 10, wherein the third positioning area is formed on a surface of the temporary carrier; the third positioning area is adjacent to the second positioning area and away from the first positioning area.
